(19) United States
(12) Patent Application Publication
(10) Pub. No.: US 2025/0019568 A1
(43) Pub. Date: Jan. 16, 2025

(54) Tungsten Chemical Mechanical Polishing Slurries

(71) Applicant: Versum Materials US, LLC, Tempe, AZ (US)

(72) Inventors: MATTHIAS STENDER, Phoenix, AZ (US); AGNES DERECSKEI, Fountain Hills, AZ (US); BRADLEY BRENNAN, Omaha, NE (US)

(21) Appl. No.: 18/713,260

(22) PCT Filed: Nov. 29, 2022
(86) PCT No.: PCT/US2022/080603

§ 371 Date: May 24, 2024

Related U.S. Application Data
(60) Provisional application No. 63/264,801, filed on Dec. 2, 2021.

(51) Int. Cl. C09G 1/02; B24B 37/20; H01L 21/321

(52) U.S. Cl. CPC C09G 1/02; B24B 37/20; H01L 21/3212

(57) ABSTRACT

This invention pertains to slurries, methods and systems that can be used in chemical mechanical planarization (CMP) of tungsten containing semiconductor device. CMP slurries comprising silica particles optionally treated with alkoxy silane amine compounds, oxidizing agent, at least one nitrogen-containing polymeric additive, an activator for tungsten polishing show improvement on removal rate of tungsten and removal selectivity of tungsten vs TEOS without affecting dishing and erosion topography.

### CROSS REFERENCE TO RELATED PATENT APPLICATIONS

The present patent application claims the benefit of U.S. Provisional Patent Application Ser. No. 63/264,801 filed on Dec. 2, 2021, which is entirely incorporated herein by reference.

### BACKGROUND

This invention pertains to slurries, systems and methods used for Chemical Mechanical Polishing or Planarization (CMP) of semiconductor devices, particularly for materials containing tungsten.

Integrated circuits are interconnected through the use of well-known multilevel interconnections. Interconnection structures normally have a first layer of metallization, an interconnection layer, a second level of metallization, and typically third and subsequent levels of metallization. Interlevel dielectric materials such as silicon dioxide and sometimes low-k materials are used to electrically isolate the different levels of metallization in a silicon substrate or well. The electrical connections between different interconnection levels are made through the use of metallized vias and in particular tungsten vias. U.S. Pat. No. 4,789,648 describes a method for preparing multiple metallized layers and metallized vias in insulator films. In a similar manner, metal contacts are used to form electrical connections between interconnection levels and devices formed in a well. The metal vias and contacts are generally filled with tungsten and generally employ an adhesion layer such as titanium nitride (TiN) and/or titanium to adhere a metal layer such as a tungsten metal layer to the dielectric material.

In one semiconductor manufacturing process, metallized vias or contacts are formed by a blanket tungsten deposition followed by a CMP step. In a typical process, via holes are etched through the interlevel dielectric (ILD) to interconnection lines or to a semiconductor substrate. Next, a thin adhesion layer such as titanium nitride and/or titanium is generally formed over the ILD and is directed into the etched via hole. Then, a tungsten film is blanket deposited over the adhesion layer and into the via. The deposition is continued until the via hole is filled with tungsten. Finally, the excess tungsten is removed by CMP to form metal vias.

In another semiconductor manufacturing process, tungsten is used as a gate electrode material in the transistor because of its superior electrical characteristics over poly-silicon which has been traditionally used as gate electrode material, as taught by A. Yagishita et al, IEEE TRANSACTIONS ON ELECTRON DEVICES, VOL. 47, NO. 5, MAY 2000.

In a typical CMP process, the substrate is placed in direct contact with a rotating polishing pad. A carrier applies pressure against the backside of the substrate. During the polishing process, the pad and table are rotated while a downward force is maintained against the substrate back. An abrasive and chemically reactive solution, commonly referred to as a polishing “slurry”, a polishing “composition” or a polishing “formulation”, is deposited onto the pad during polishing, where rotation and/or movement of the pad relative to the wafer brings said slurry into the space between the polishing pad and the substrate surface. The slurry initiates the polishing process by chemically reacting with the film being polished. The polishing process is facilitated by the rotational movement of the pad relative to the substrate as slurry is provided to the wafer/pad interface. Polishing is continued in this manner until the desired film on the insulator is removed. Removal of tungsten in the CMP is believed to be due to synergy between mechanical abrasion and tungsten oxidation followed by dissolution.

One of the commonly encountered problems in CMP in particular in metal applications such as tungsten are dishing of tungsten lines and erosion of arrays of metal lines. Tungsten CMP slurries have to be formulated such that the dishing and erosion can be minimized in order to meet certain design targets critical for a functioning device.

There still has been a need for novel CMP tungsten slurries that can reduce erosion while maintain desirable removal rate in polishing.

### SUMMARY

The present invention relates to CMP slurries, systems and methods of using the CMP slurries to reduce dishing while maintain desirable removal rate in polishing semiconductor device or substrate. More specifically, the present invention relates to CMP slurries, system and method of using the CMP slurries to provide high selectivity tungsten slurry with excellent dishing and erosion performance in polishing semiconductor device or substrate containing tungsten.

In one aspect, the present disclosure provides a polishing composition comprising: water; from 0.05 wt. % to 10.0 wt. % of abrasive particles comprising silica; from 0.005 wt. % to 0.5 wt. % of a soluble activator compound; from 0.5 wt. % to about 10.0 wt. % of an oxidizer; at least one nitrogen-containing polymeric additive selected from the group consisting of chitosan, a polyacrylamide, a polyamine, a polyethylenimine, poly(N-vinyl-N-methyl amine), polyaminostyrene, a polyvinylamine, a polyvinyl amine; and optionally, a corrosion inhibitor; a stabilizer; a pH-adjusting agent; a water-miscible organic solvent; a surfactant; and a biocide or biological growth inhibitor, wherein the polishing composition has a pH between 1 and 7.

In another aspect, provided herein is a polishing composition comprising: water; from 0.05 wt. % to 10.0 wt. % of abrasive particles comprising silica; from 0.005 wt. % to 0.5 wt. % of a soluble activator compound; from 0.5 wt. % to about 10.0 wt. % of an oxidizer; at least one water-soluble cationic polysaccharide is at least one represented by the general formula:

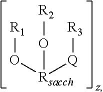

wherein R_{sacch} is the residue of a polysaccharide repeat unit derived from the polysaccharide staring material; Q is selected from the group consisting of

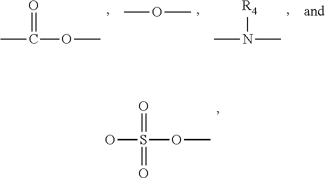

wherein R₄ is selected from the group consisting of

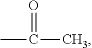

and a mixture of

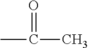

and hydrogen;
Z is from 50 to about 20,000; and each of R1, R2, and R3 is independently represented by the substituent structural formula:

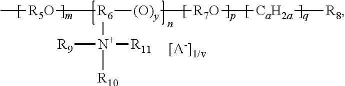

wherein A is an anion; a is an integer of from 1 to about 3; m is an integer of from 0 to about 6; n is an integer of from 0 to about 3, provided that the level of cationic substitution, CS, defined by the average moles of quaternary nitrogen atoms per mole polysaccharide repeat unit is greater than 0; p is an integer of from 0 to about 6; q is 0 or 1; each R₅ and R₇ is individually ethylene, a propylene or a hydroxypropylene; R₆ is a di-or trivalent, branched or straight chain, saturated or unsaturated hydrocarbon having from 2 to about 4 carbon atoms, provided there are at least 2 carbon atoms between the nitrogen atom and any oxygen atom; R₈ is hydrogen, hydroxyl, Rₕ, carboxyl or alkali metal or amine carboxylate, provided that when q is 0 then R₈ is hydrogen or Rₕ; each R₉, R₁₀ and R₁₁ is individually Rh, alkyl, aryl, aralkyl, alkaryl, cycloalkyl, alkoxyaryl or alkoxyalkyl, having at least two carbon atoms separating the oxygen atom in the alkoxyaryl or alkoxyalkyl group from the nitrogen atom; Rₕ is a hydrophobic group containing an alkyl group having at least 8 carbon atoms; v is equal to the valence of A; and y is 0 or 1, wherein the polishing composition has a pH between 1 and 7.

In another aspect provided herein is a polishing method for chemical mechanical planarization of a semiconductor device comprising at least one surface containing tungsten, the method comprising the steps of: contacting the at least one surface containing tungsten with a polishing pad; delivering a polishing composition comprising: water; from 0.05 wt. % to 10.0 wt. % of abrasive particles comprising silica; from 0.005 wt. % to 0.5 wt. % of a soluble activator compound; from 0.5 wt. % to about 10.0 wt. % of an oxidizer; at least one nitrogen-containing polymeric additive selected from the group consisting of chitosan, a polyacrylamide, a polyamine, a polyethylenimine, poly(N-vinyl-N-methyl amine), polyaminostyrene, a polyvinylamine, a polyvinyl amine; and optionally, a corrosion inhibitor; a stabilizer; a pH-adjusting agent; a water-miscible organic solvent; a surfactant; and a biocide or biological growth inhibitor, wherein the polishing composition has a pH between 1 and 7, to the at least one surface containing tungsten; and c) polishing the at least one surface containing tungsten with the polishing composition; wherein polishing rate for tungsten at 3 psi down-force is >4000 Å/min.

### BRIEF DESCRIPTION OF THE DRAWINGS

The present invention will hereinafter be described in conjunction with the appended figures wherein like numerals denote like elements:

FIG. 1 shows removal rates for tungsten(W) and TEOS and removal selectivity of W:TEOS using different formulations;

FIG. 2 shows the dishing measured on tungsten patterned wafers using different formulations;

FIG. 3 shows the erosion measured on tungsten patterned wafers using different formulations;

FIG. 4 is a graph illustrating the erosion inhibition effect of chitosan at varying concentrations for a 1μ feature;

FIG. 5 is a graph illustrating the erosion inhibition effect of chitosan at varying concentrations for a 0.25μ feature;

FIG. 6 is a graph illustrating the erosion inhibition effect of chitosan at varying concentrations for a 0.18μ feature;

FIG. 7 is a graph illustrating the dishing inhibition effect of various compostions disclosed herein for a 10μ feature; and

FIG. 8 is a graph illustrating the dishing inhibition effect of various compostions disclosed herein for a 1μ feature.

### DETAILED DESCRIPTION

Formation of conducting metal features in semiconductor device wafer fabrication steps comprise patterning the wafer, etching line trenches or vias in the dielectric materials, filling those vias or line trenches with conducting metals and then performing chemical mechanical planarization (CMP) step to remove excess metal and provide a very planar surface. Critical CMP parameters that define the planarity of the polished wafers are dishing and erosion. Dishing refers to the depression in an individual line or via relative to the field level. Dishing is primarily a significant issue for larger features (typically greater than 1 micron) and in low patterned density areas. Erosion is the depression of an array of metal structures compared to the field level. Erosion is generally more problematic for dense arrays of narrow metallic structures with feature sizes 10 micron or less and patterned metal density of 50% or more.

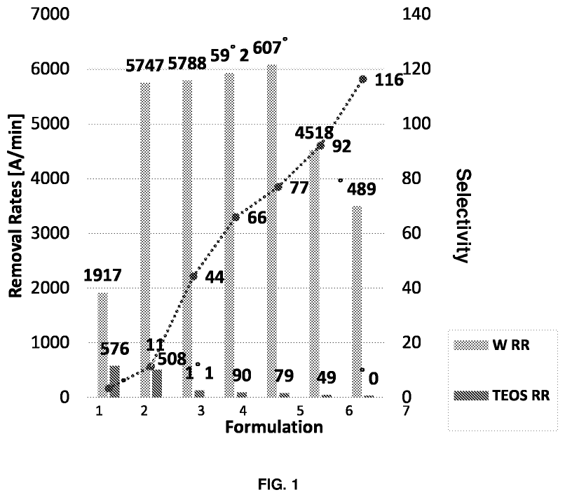

Representations of a dishing and erosion topography observed after CMP is shown in FIG. 1 in Elbel et al, J. Electrochem Soc., Col. 145, No. 5, May 1998 pp. 1659-1664.

Present invention pertains to slurries that can be used in chemical mechanical planarization (CMP) of tungsten containing semiconductor devices, substrates, or films. CMP slurries of present invention provide the unique result of reduced dishing of tungsten structures and reduced erosion of dielectric materials, while providing high removal rates.

Tungsten film may be purely tungsten or may contain alloying elements.

Formulations of this invention may be suitable for many types of dielectric used in patterned structures. Examples of dielectric materials include but not limited to thermal oxide, Tetra Ethyl Ortho Silicate (TEOS), High Density Plasma (HDP) oxide, High Aspect Ratio Process (HARP) films, fluorinated oxide films, doped oxide films, organosilicate glass (OSG) low-K dielectric films, Spin-On Glass (SOG), polymer films, flowable Chemical Vapor Deposited (CVD), silicon nitride, silicon carbide, silicon oxy carbide, silicon oxy nitride, silicon oxy carbide nitride

In some other embodiments, the desired polishing selectivity between tungsten and TEOS removal rate is greater than 25 or preferably greater than 40 or more preferably greater than 90.

The CMP slurries comprise silica particles with surface treated with alkoxy silane amine compounds, oxidizing agent, an activator for tungsten polishing, water based solvent, with pH of the slurry is between 2 and 14, preferably is between 1 and 7, and more preferably is between 2 and 5.

The silica particles treated with alkoxy silane amine are free of shell structures modified by alkoxy silane.

The size of the particles as measured by dynamic light scattering is between 10 nm and 300 nm, preferably between 20 nm and 200 nm, or more preferably between 30 and 100 nm; and the zeta potential on the particles is 15 mV, preferably ≥20 mV, or more preferably ≥25 mV.

The CMP slurries may as optionally comprise surfactants; stabilizing and passivating agents; dispersion agents; chelators; film-forming anticorrosion agents; dishing reducing agents and a polish enhancement agent.

In certain preferred embodiments, the polish rates of tungsten blanket films at 3.0 psi downforce and 80 RPM table speed is greater than 2500 Å/min., preferably greater than 3000 Å/min., more preferably greater than 4000 Å/min., or most preferably greater than 4500 Å/min.; while the polishing rates of TEOS is <150 Å/min., preferably 80 Å/min., or more preferably <50 Å/min.

In certain preferred embodiments, the erosion of 9×1 micron array (9 micron wide tungsten line width separated by 1 micron wide dielectric line) measured on a patterned wafer is less than 1000 Å, preferably less than 500 Å or more preferably less than 300 Å when the wafer is polished for 15 seconds additional time after the pattern wafer polish end point detected by using is suitable method such as eddy current measurement or optical end point detection.

### Abrasive

CMP slurry compositions disclosed herein comprise 0.01 wt. % to 10.0 wt. %; 0.01 wt. % to 2.0 wt. %; 0.01 wt. % to 0.5 wt. % of abrasive particles that optionally include surface modified silica particles with their surfaces treated with alkoxy silane amine compounds.

The abrasive is generally in the form of an abrasive particle, and typically many abrasive particles, of one material or a combination of different materials.

Generally, a suitable abrasive particle is more or less spherical or cocoon shaped and has an effective diameter of between 10 to 300 nm, preferably 20 and 200 nm, or more preferably between 30 to 100 nm.

Abrasive in the form of aggregated or agglomerated particles are preferably processed further to form individual abrasive particles.

Particle size may be measured by any suitable technique including but not limited to Static Light Scattering, Dynamic Light Scattering, Hydrodynamic Fluid Fractionation, Sedimentation Analysis, Electrical Sensing Zone Analysis and Dynamic Image Analysis, disc centrifuge analysis. A preferred method for particle size and distribution measurement is dynamic light scattering.

In some embodiments, the abrasive particles do not have their surface modified. In other embodiments, the abrasive particles are silica particles having their surfaces treated with alkoxy silane amine compound.

The silica particles may be produced by any suitable techniques including, but not limited to sol-gel, hydrothermal, hydrolytic, plasma, pyrogenic, aerogel, fuming and precipitation techniques, and any combination thereof.

In preferred embodiments the alkoxy silane amine compounds used for treating the silica particle surface also include amino groups.

Alkoxy silane amine compound can be represented by following general structure

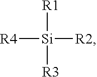

where R₁, R₂, R₃ and R₄ are independently selected from an alkyl or aryl group or a hydrozyable group such as alkoxy, acyloxy, halogen or amine group, wherein at least one of the R groups is an alkoxy group and at least one of the R groups is an amine group.

In some preferred embodiments R₁, R₂ and R₃ comprise alkoxy functional group and R₄ comprises an amine group.

Examples of preferred alkoxy silanes include but not limited to (3-Aminopropyl)trimethoxysilane, 3-aminopropyltriethoxysilane, 4-aminobutyltriethoxysilane, m-aminophenyltrimethoxysilane, p-aminophenyltrimethoxysilane, 3-aminopropyltris(methoxyethoxy ethoxy)silane, 11-aminoundecyltriethoxysilane, 2-(4-pyridylethyl)triethoxysilane.

The alkoxy silane amine modified particles in the CMP slurries disclosed herein do not include activator compound attached to them.

Surface treatment with alkoxy silane amine compound occurs only on the surface of the particles. There is no shell formation surrounding the core silica particles.

Zeta potentials of the particles in the slurry and DI water is 15 mV, preferably ≥20 mV, or more preferably ≥25 mV.

The size of the particles as measured by dynamic light scattering is between 10 to 300 nm, preferably ≥20 to 200 nm, or more preferably between 30 to 100 nm.

In certain preferred embodiments, the abrasive is a cocoon-shaped aggregate particle.

A slurry may have more than one type of abrasive, and it may be advantageous to have different sizes for different types of abrasives.

One type of abrasive can be metal oxide, a metal oxide or metalloid oxide or a chemical mixture of metal oxides or metalloid oxides.

Suitable metal oxide abrasive includes, but is not limited to, alumina, ceria, germania, silica, spinel, titania, an oxide or nitride of tungsten, zirconia, or any of the above doped with one or more other minerals or elements, and any combination thereof. The metal oxide abrasive may be produced by any of a variety of techniques, including sol-gel, hydrothermal, hydrolytic, plasma, pyrogenic, aerogel, fuming and precipitation techniques, and any combination thereof.

Precipitated metal oxides and metalloid oxides can be obtained by known processes by reaction of metal salts and acids or other precipitating agents. Pyrogenic metal oxide and/or metalloid oxide particles are obtained by hydrolysis of a suitable, vaporizable starting material in an oxygen/hydrogen flame. An example is pyrogenic silicon dioxide from silicon tetrachloride. The pyrogenic oxides of aluminum oxide, titanium oxide, zirconium oxide, silicon dioxide, cerium oxide, germanium oxide and vanadium oxide and chemical and physical mixtures thereof are suitable.

The abrasive may be a mixed oxide such as consisting of the two molecular species SiO₂ and Al₂O₃. Abrasives comprising alumina coated silica can also be useful.

In one preferred embodiment, the metal oxide abrasive is a precipitated or fumed abrasive, and preferably a fumed abrasive. By way of example, a fumed metal oxide abrasive may be a fumed silica or fumed alumina or a fumed silica/alumina.

Abrasive particles may be purified using suitable method such as ion exchange to remove metal impurities such as sodium, potassium, aluminum, iron, etc. Alternatively high purity silica particles are used. In certain preferred embodiments the total metal content in the silica particles is less than 100 ppm or more preferably less than 10 ppm or most preferably less than 1 ppm.

In general, the above-mentioned abrasives may be used either alone or in combination with one another. Two or more abrasive particles with different sizes may also be combined to obtain excellent performance.

In most embodiments of the present invention, the abrasive is selected from the group consisting of colloidal silica; fumed silica; alumina; titania; ceria; zirconia; surface modified particles selected from the group consisting of activator-containing particles, composite particles, and lattice doped and inorganic oxide particles; and combinations thereof.

The concentration of abrasive can range from 0.01 wt. % to 30 wt. %, the preferred is from about 0.05 wt. % to about 10 wt. %, the more preferred is from about 0.1 and 2 wt. %. The weight percent is relative to the total weight of the composition.

### Additives for Dishing Reduction or Tungsten Corrosion Inhibition

Slurry formulation may comprise an additive to reduce dishing for tungsten features or to reduce tungsten etching and corrosion during CMP.

Additives used in the slurries include, but are not limited to sarcosinates, related carboxylic compounds, and hydrocarbon substituted sarcosinate; organic polymer and copolymer having molecules containing ethylene oxide repeating units, such as polyethylene oxide (PEO), and ethoxylated surfactants, nitrogen containing heterocycles without nitrogen-hydrogen bonds, sulfides, oxazolidines or mixtures of functional groups in one compound, nitrogen containing compounds having three or more carbon atoms that form alkylammonium ions, amino alkyls having three or more carbon atoms, polymeric corrosion inhibitors comprising repeating group of at least one nitrogen-containing heterocyclic ring or a tertiary or quaternary nitrogen atom such as cetyltrimethylammonium hydroxide, polyacationic amine compounds, cyclodextrin compounds, polyethyleimine compounds, glycolic acid, chitosan, sugar alcohols, polysaccharides, alginate compounds, phosphonium compounds, sulfonic acid polymers, amidine compounds, and polyacrylamides.

Preferred additives for reducing dishing and corrosion are nitrogen-containing polymeric additives. The nitrogen-containing polymeric additive may comprise a polymeric polyamine, for example chitosan, a polyacrylamide, a polyamine, a polyethylenimine, poly(N-vinyl-N-methyl amine), polyaminostyrene, a polyvinylamine, a polyvinyl amine (which may be a homopolymer or a copolymer).

In embodiments where the nitrogen-containing polymeric additive comprises the polyamine, the polyamine may comprise a diamine selected from 1,2-diaminoethane, 1,4-diaminobutane, 1,5-diaminopentane, 1,6-diaminohexane (hexamethylenediamine, HMDA), 1,12-diaminododecane, 1,4-diaminocyclohexane, 1,4-diaminobenzene, 1,5-diamino-2-methylpentane (2-methyl-pentamethylenediamine), 1,3-pentanediamine, and 1,8-diaminooctane. The nitrogen-containing reactant may comprise a primary polyamine polyether-polyamine; said polyether-polyamine may be a diamine or a triamine. In one embodiment, the polyether-polyamine is a trifunctional primary amine having an average molecular weight of 440 known as Jeffamine T-403 Polyetheramine (Huntsman Corporation).

Generally speaking, for nitrogen-containing polymeric additives such as, for example, polyacrylamides, the molecular weight of the polymeric additive is in a range from about 200 MW to about 500,000 MW, more preferably about 500 MW to about 100,000 MW, even more preferably about 1,000 MW to about 20,000 MW, and most preferably about 5000 MW to about 15,000 MW, where MW corresponds to molecular weight in grams per mole. Preferably, the polymeric additive(s) do not substantially deposit on the surface of the microelectronic device.

In some embodiments, chitosan is the additive. Chitosan has the following structure:

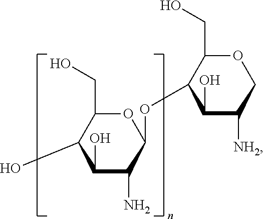

wherein n is a number from 20 to 2250 and preferably from 50 to 1500; or 200 to 1000. Preferably, the chitosan employed is from 70% to 90% or 75% to 85% deacetylated.

In some embodiments, the compositions disclosed herein comprise at least one water-soluble cationic polysaccharide as an additive to reduce dishing on tungsten metal.

The water-soluble cationic polysaccharides of this invention may be produced from readily available materials. Such polysaccharides are derived from naturally occurring polysaccharides, or those modified by etherification, which are quaternized with a nitrogen-containing compound and alkylated with a compound, including a nitrogen-containing compound, containing a hydrophobe.

Polysaccharide starting materials include the naturally occurring, biosynthesized and derivatized carbohydrate polymers or mixtures thereof. Such materials encompass high molecular weight polymers composed of monosaccharide units joined by glycosidic bonds. These materials include the entire starch and cellulose families; pectin; chitosan; chitin; the seaweed products such as agar and carrageenan; alginate; the natural gums such as guar, arabic and tragacanth; bio-derived gums such as xanthan; and the like.

Preferred starting materials include cellulosics conventionally employed for the preparation of cellulose ethers, such as chemical cotton, cotton linters, wood pulp, alkali cellulose, and the like and ether derivatives of the same. Such cellulose ethers include hydroxyethyl cellulose, hydroxypropyl cellulose, methyl cellulose, carboxymethyl cellulose, carboxyethyl cellulose, hydroxypropyl methyl cellulose, hydroxyethyl methyl cellulose, hydroxyethyl carboxymethyl cellulose, and the like. A particularly preferred polysaccharide starting material is hydroxyethyl cellulose. The polysaccharide starting material possesses a molecular weight corresponding to the number of polysaccharide repeat units, usually from 50 up to about 20,000. The molecular weight of the polysaccharides may be varied through controlled degradation procedures known in the art.

Etherified polysaccharides may be obtained commercially or produced from the polysaccharide starting materials mentioned previously. Etherification involves reacting pendent hydroxyl groups on the polysaccharide backbone with an etherifying agent, or mixtures thereof, which contain functional groups reactive with such hydroxyl groups. Etherification may be conducted to enhance the water-solubility of the polysaccharides, e.g. by ethoxylation. Typical etherifying agents include lower alkylating agents such as dimethyl sulfate, diethyl sulfate, methyl chloride, methyl bromide, ethyl chloride, ethyl bromide or n-propyl chloride; hydroxy alkylating agents such as ethylene oxide, propylene oxide or glycidol; and carboxy alkylating agents such as monochloroacetic acid, sodium chloroacetate or chloropropionic acid.

The polysaccharide starting materials are provided with quaternary nitrogen-containing substituents through quaternization reactions. Quaternization may be achieved by reacting the polysaccharides with quaternizing agents which are quaternary ammonium salts, including mixtures thereof, to effect substitution of the polysaccharide chain with quaternary nitrogen-containing groups. Typical quaternary ammonium salts which can be utilized include quaternary nitrogen-containing halides, halohydrins and epoxides. The quaternary ammonium salt may contain hydrophobes. Exemplary ammonium salts include one or more of the following:
3-chloro-2-hydroxypropyl dimethyldodecyl ammonium chloride; 3-chloro-2-hydroxypropyl dimethyloctadecyl ammonium chloride; 3-chloro-2-hydroxypropyldimethyloctyl ammonium chloride;
3-chloro-2-hydroxypropyl trimethyl ammonium chloride; 2-chloroethyl trimethyl ammonium chloride; 2,3-epoxypropyl trimethyl ammonium chloride; and the like. Preferred quaternization agents include 3-chloro-2-hydroxypropyl trimethyl ammonium chloride; 3-chloro-2-hydroxypropyl dimethyldodecyl ammonium chloride; 3-chloro-2-hydroxypropyl dimethyltetradecyl ammonium chloride;
3-chloro-2-hydroxypropyl dimethylhexadecyl ammonium chloride; and 3-chloro-2-hydroxypropyl dimethyloctadecyl ammonium chloride.

Suitable water-soluble cationic polysaccharides can be made according to the disclosure of U.S. Pat. No. 4,663,159, which is incorporated herein by reference.

In some embodiments, the cationic polysaccharides used herein as an additive to prevent tungsten dishing are represented by the general formula:

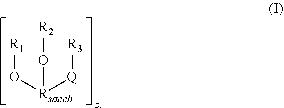

In Formula I, R_{sacch} is the residue of a polysaccharide repeat unit derived from the polysaccharide starting materials previously described. The polysaccharide repeat unit may contain more than three “R” substituents for those polysaccharides which contain more than three reactive hydroxyl groups per repeat unit, as in for example xanthan gum which provides up to 11 hydroxyl groups per repeat unit available for etherification, quaternization or alkylation. R_{sacch} is preferably the residue of an anhydroglucose repeat unit, particularly from cellulose.

The parameter Q in Formula I varies depending upon the particular polysaccharide being utilized. For example, Q is —O— when the particular polysaccharide comprises anhydroglucose repeat units such as in starch, cellulose or the like.

### Similarly, Q is

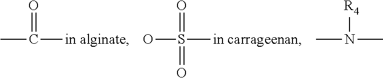

wherein R₄ is a mixture of hydrogen and

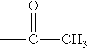

groups in chitosan. Q is preferably —O—, i.e., an oxygen atom.

The number of polysaccharide repeat units, defined by z in Formula I, is usually from about 50 to about 20,000, preferably from about 100 to about 6,000; and most preferably from about 250 to about 4,000. The corresponding molecular weights of the hydrophobe substituted, cationic polysaccharide will usually range from several thousand up to several million.

The R₁, R₂ and R₃ substituents in Formula I are either hydrogen, when representing unreacted hydroxyl groups of the polysaccharide, or those substituents provided by etherification, quaternization and/or alkylation. Each R₁, R₂ and R₃ is individually represented by the substituent structural formula (II):

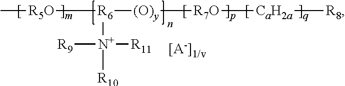

In Formula II, A is an anion, including mixtures of anions. Exemplary anions include inorganic anions such as chloride, bromide, iodide, sulfate, methylsulfate, sulfonate, nitrate, phosphate, and the like; and organic anions such as acetate, and the like. Monovalent anions are preferred, particularly halides, and especially chloride. The anions are typically provided as the residue of the quaternary ammonium salts used as quaternizing agents, or by ion exchange techniques.

The alkylene substituent defined by a in Formula II, contains from 1 to about 3 carbon atoms such that a is an integer having a value of from 1 to about 3.

The extent of etherification due to oxyalkylene substituents, as defined by m and p in Formula II, ranges from 0 to about 6 oxyalkylene groups each, i.e., m is an integer of from 0 to about 6 and p is an integer of from 0 to about 6. The additional extent of etherification, as defined by q in Formula II, depends upon the absence or presence of the alkylene group, i.e., Cₐ H₂ₐ, such that q is 0 or 1, preferably 0.

The total extent of etherification, is usually greater than 0, preferably from about 1.2 to about 4.5, and most preferably from about 1.8 to about 3.6.

The number of quaternary nitrogen atoms per substituent, defined by n in Formula II, is from 0 to about 3, i.e., n is an integer of from 0 to about 3. The extent of quaternization, characterized as CS as discussed previously, is greater than 0, preferably less than 1 and most preferably from about 0.01 to about 0.6.

Each R₅ and R₇ in Formula II, defining the oxyalkylene substituent, is individually an ethylene (providing oxyethylene), a propylene (providing oxypropylene) or a hydroxypropylene (providing hydroxy substituted oxypropylene) unit. R₅ and R₇ are preferably ethylene or isopropylene, and most preferably ethylene.

The segment connecting the quaternary nitrogen to the polysaccharide molecule, defined as R₆ in Formula II, is a di- or a trivalent, branched or straight chain, saturated or unsaturated hydrocarbon having from 2 to about 4 carbon atoms, provided that there are at least 2 carbon atoms between the nitrogen atom and any oxygen atom, such as in the ether substituent or polysaccharide residue. R₆ can be ethylene, a C₃ hydrocarbon group, or —CH₂CH═CHCH₂—, and most preferably is

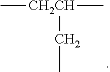

R₈ in Formula II is hydrogen, hydroxyl, Rₕ as hereinafter defined, carboxyl or alkali metal or amine carboxylate, provided that when q is 0 then R₈ is hydrogen or Rₕ.

R₈ is preferably hydrogen or Rₕ. When R₈ is hydrogen and m, n, p and q are all 0 the substituent structural formula provides an unsubstituted polysaccharide hydroxyl group.

The nitrogen substituents, defined by R₉, R₁₀ and R₁₁ in Formula II, are each individually Rₕ, alkyl, aryl, aralkyl, alkaryl, cycloalkyl, alkoxyalkyl or alkoxyaryl. If an alkoxyalkyl or alkoxyaryl substituent is provided, at least two carbon atoms separate the substituent oxygen atom from the nitrogen atom. Nitrogen substituents free of hydrophobes include: lower alkyls having from 1 to about 3 carbon atoms, such as methyl, or ethyl; aryls such as phenyl; aralkyls such as benzyl; and the like. Preferably at least two nitrogen substituents of each repeat unit are methyl, and the remaining substituent is Rₕ or a mixture of Rₕ and methyl among the nitrogen-containing repeat units in the polysaccharide molecule.

The hydrophobe, defined by Rₕ in Formula II, contains a long chain alkyl group having at least 8 carbon atoms, preferably from about 10 to about 24 carbon atoms and most preferably from about 10 or 12 to about 18 carbon atoms. Hydrophobes containing alkyl groups which have less than 8 carbon atoms or aryl groups will generally not provide sufficient hydrophobic substitution to the quaternary nitrogen-containing polysaccharides to produce the superior combination of properties exhibited by the hydrophobe substituted polysaccharides of this invention.

The polysaccharides disclosed herein, in addition to possessing substantial water-solubility, contain hydrophobes comprised of 8 or more alkyl carbon atoms in an amount sufficient to provide enhanced viscosification, foaming, and preferably surface tension lowering, of aqueous solutions containing the polysaccharides, as well as significant personal care utility. Preferred polysaccharides of this invention can provide significant personal care utility even at the expense of providing only modest enhancement in viscosity, foaming or surface tension properties.

Rₕ may be attached directly to the quaternary nitrogen when present as R₉, R₁₀ or R₁₁; to the ether substituents as R₈; and/or directly to the polysaccharide residue as R₈ when m, n, p and q are all 0. The hydrophobes may be provided at any or all of these locations, in the same or different repeat units within the polysaccharide molecule.

Rₕ may also contain a connecting segment between the alkyl and the ether oxygen atom depending upon the functional group contained in the alkylating agent used to connect the alkyl group to the polysaccharide. For example, Rₕ may be: an alkyl group when an alkyl halide is the alkylating agent; an a-hydroxyalkyl group when an epoxide is the alkylating agent; a urethane alkyl group when an isocyanate is the alkylating agent; an acyl alkyl group when the alkylating agent is a carboxylic acid or acyl halide; and so on. Rₕ is preferably a long chain alkyl group bonded directly to an oxygen atom or most preferably, to the quaternary nitrogen atom.

The valence of anion A, defined as v in Formula II, is an integer, preferably 1.

The absence or presence of the ether oxygen in the quaternary nitrogen substituent is defined by y in Formula II, i.e., y is 0 or 1, respectively, provided that in the absence of further ether substitution, i.e., when n is greater than 0 and y is 0, then p and q are 0 and R₈ is hydrogen. Preferably y is 1.

The amount of these additives range from 0.0001 wt. % to about 2.0 wt. %; preferably from about preferred 0.001 wt. % to 1.0 wt. %, and more preferred 0.01 wt. % to about 0.5 wt. %.

In one embodiment, the water-soluble cationic polysaccharide is at least one represented by the general formula:

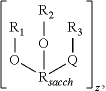

wherein
R_{sacch} is the residue of a polysaccharide repeat unit derived from the polysaccharide staring material;
Q is selected from the group consisting of

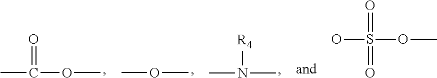

wherein R₄ is selected from the group consisting of

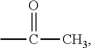

and a mixture of

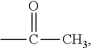

and hydrogen;
Z is from 50 to about 20,000; and each of R1, R2, and R3 is independently represented by the substituent structural formula:

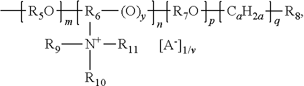

wherein
A is an anion;
a is an integer of from 1 to about 3;
m is an integer of from 0 to about 6;
n is an integer of from 0 to about 3, provided that the level of cationic substitution, CS, defined by the average moles of quaternary nitrogen atoms per mole polysaccharide repeat unit is greater than 0;
p is an integer of from 0 to about 6;
q is 0 or 1;
each R₅ and R₇ is individually ethylene, a propylene or a hydroxypropylene;
R₆ is a di- or trivalent, branched or straight chain, saturated or unsaturated hydrocarbon having from 2 to about 4 carbon atoms, provided there are at least 2 carbon atoms between the nitrogen atom and any oxygen atom;
R₈ is hydrogen, hydroxyl, Rₕ, carboxyl or alkali metal or amine carboxylate, provided that when q is 0 then R₈ is hydrogen or Rₕ
each R₉, R₁₀ and R₁₁ is individually Rh, alkyl, aryl, aralkyl, alkaryl, cycloalkyl, alkoxyaryl or alkoxyalkyl, having at least two carbon atoms separating the oxygen atom in the alkoxyaryl or alkoxyalkyl group from the nitrogen atom;
Rₕ is a hydrophobic group containing an alkyl group having at least 8 carbon atoms;
v is equal to the valence of A; and
y is 0 or 1.

In some embodiments, when y is 0 then p and q are 0 and R₈ is hydrogen.

In some embodiments, the additive is selected from the group consisting of at least one polyamine and at least one polyacrylamide. In some embodiments, the additive includes chitosan and a polyacrylamide. In other embodiments, the additive includes chitosan and a polyether-polyamine (Jeffamine T-403). In yet other embodiments, the additive includes chitosan, a polyacrylamide, and a polyether-polyamine.

### Oxidizer

The CMP slurries of the present invention comprise 0.1 wt. % to about 10.0 wt. %; 0.5 wt. % to 5.0 wt. %; 1.0 wt. % to 3.0 wt. % of an oxidizer for chemical etching of material. The oxidizing agent of the CMP slurry is in a fluid composition which contacts the substrate and assists in the chemical removal of targeted material on the substrate surface. The oxidizing agent component is thus believed to enhance or increase the material removal rate of the composition. Preferably, the amount of oxidizing agent in the composition is sufficient to assist the chemical removal process, while being as low as possible to minimize handling, environmental, or similar or related issues, such as cost.

Advantageously, in one embodiment of this invention, the oxidizer is a component which will, upon exposure to at least one activator, produce free radicals giving an increased etching rate on at least selected structures. The free radicals described infra will oxidize most metals, and will make the surface more susceptible to oxidation from other oxidizers. However, oxidizers are listed separately from the “Compound Producing Free Radicals”, to be discussed infra, because some oxidizers do not readily form free radicals when exposed to the activators, and in some embodiments it is advantageous to have one or more oxidizers which provide matched etching or preferential etching rates on a variety of combinations of metals which may be found on a substrate.

As is known in the art, some oxidizers are better suited for certain components than for other components. In some embodiments of this invention, the selectivity of the CMP system to one metal as opposed to another metal is maximized, as is known in the art. However, in certain embodiments of present invention, the combination of oxidizers is selected to provide substantially similar CMP rates (as opposed to simple etching rates) for a conductor and a barrier combination.

In one embodiment, the oxidizing agent is an inorganic or organic per-compound.

A per-compound is generally defined as a compound containing an element in its highest state of oxidation, such as perchloric acid; or a compound containing at least one peroxy group (—O—O—), such as peracetic acid and perchromic acid.

Suitable per-compounds containing at least one peroxy group include, but are not limited to, peracetic acid or salt thereof, a percarbonate, and an organic peroxide, such as benzoyl peroxide, urea hydrogen peroxide, and/or di-t-butyl peroxide.

Suitable per-compounds containing at least one peroxy group include peroxides. As used herein, the term “peroxides” encompasses R—O—O—R′, where R and R′ are each independently H, a C₁ to C₆ straight or branched alkyl, alkanol, carboxylic acid, ketone (for example), or amine, and each of the above can independently be substituted with one or more benzyl group (for example benzoyl peroxide) which may themselves be substituted with OH or C₁-C₅ alkyls, and salts and adducts thereof. This term therefore includes common examples such as hydrogen peroxide, peroxyformic acid, peracetic acid, propaneperoxoic acid, substituted or unsubstituted butaneperoxoic acid, hydroperoxy-acetaldehyde, Also encompassed in this term are common complexes of peroxides, for example urea peroxide.

Suitable per-compounds containing at least one peroxy group include persulfates. As used herein, the term “persulfates” encompasses monopersulfates, di-persulfates, and acids and salts and adducts thereof. Included for example is peroxydisulfates, peroxymonosulfuric acid and/or peroxymonosulfates, Caro's acid, including for example a salt such as potassium peroxymonosulfate, but preferably a non-metallic salt such as ammonium peroxymonosulfate.

Suitable per-compounds containing at least one peroxy group include perphosphates, defined as above and including peroxydiphosphates.

Also, ozone is a suitable oxidizing agent either alone or in combination with one or more other suitable oxidizing agents.

Suitable per-compounds that do not contain a peroxy group include, but are not limited to, periodic acid and/or any periodiate salt (hereafter “periodates”), perchloric acid and/or any perchlorate salt (hereafter “perchlorates”) perbromic acid and/or any perbromate salt (hereafter “perbromates”), and perboric acid and/or any perborate salt (hereafter “perbromates”).

Other oxidizing agents are also suitable components of the composition of the present invention. Iodates are useful oxidizers.

Two and more oxidizers may also be combined to obtain synergistic performance benefits.

The oxidizer concentration can range from 0.01 wt. % to 30 wt. % while the more preferred amount of oxidizing agents is from about 0.5 wt. % to about 10 wt. %. The weight percent is relative to the composition.

In most embodiments of the present invention, the oxidizer is selected from the group consisting of peroxy compound selected from the group consisting of hydrogen peroxide, urea peroxide, peroxyformic acid, peracetic acid, propaneperoxoic acid, substituted or unsubstituted butaneperoxoic acid, hydroperoxy-acetaldehyde, potassium periodate, ammonium peroxymonosulfate; and non-per-oxy compound selected from the group consisting of ferric nitrite, KClO₄, KBrO₄, KMnO₄.

### Activator

The activator or catalyst, is a material that facilitates the formation of free radicals by at least one free radical-producing compound present in the fluid. If the activator is a metal ion, or metal-containing compound, it is in a thin layer associated with a surface of a solid which contacts the fluid. If the activator is a non-metal-containing substance, it can be dissolved in the fluid. It is preferred that the activator is present in amount that is sufficient to promote the desired effect.

For example, activators or catalysts of U.S. Pat. Nos. 7,014,669, 6,362,104, 5,958,288, 8,241,375, 7,887,115, 6,930,054, US patent application numbers US2014315386, US2016280962, and Korean publication number KR1020110036294, the disclosures of which are incorporated herein by reference, can be used in this capacity.

Activator can be present in the slurry or it can be present on the polishing pad or can be present where the slurry containing oxidizer contacts the activator prior to passing between the pad and a wafer substrate.

Activators may be present in one or more different forms. Examples of different forms of activators include but are not limited to (i) soluble activator compound in the slurry (ii) particle with a surface modified with activator compound (iii) particles with activator included in the both the particle core and the surface (iv) core-shell composite particles comprising activator exposed on the surface.

In one embodiment, the activator is any metal-containing compound known to be useful in Fenton's reactions as an activator, wherein the oxidizer is a peroxide, particularly hydrogen peroxide. Transition metals like copper, manganese, cobalt, and cerium, as well as the more traditional iron and copper, are able to catalyze this reaction.

In one important embodiment, the activator comprises a metal-containing compound having the metal other than a metal of Group 4(b), Group 5(b) or Group 6(b) of the Periodic Table of Elements. In one embodiment, compounds of metals of Group 1(b) or Group 8 are preferred metal-containing activators.

Metal containing activator compounds can be used in form a soluble compound in the slurry. Suitable activator compounds for the pH range of this invention include but are not limited to ammonium iron (Ill) oxalate trihydrate, iron(Ill) citrate tribasic monohydrate, iron(Ill) acetylacetonate and ethylenediamine tetraacetic acid, iron (Ill) sodium salt hydrate. A soluble activator can also be a metal compound of Ag, Co, Cr, Cu, Fe, Mo, Mn, Nb, Ni, Os, Pd, Ru, Sn, Ti, V and mixtures thereof having multiple oxidation states. In most embodiments of the present invention, the activator includes, but is not transition metals. Compounds of metals with strong chemical ligands such as citric acid, gluconic acid, oxalic acid, ethylene diamine tetra acetic acid are generally for stable in alkaline pH.

Some of the activator compounds such as ferric nitrate, ferric sulfate, ferric citrate and iron gluconate which are stable in acidic pH such as pH<4.

The amount of soluble activator compound in a slurry ranges from about 0.0001 wt. % to about 10 wt. %; preferably 0.0005 wt. % to 2 wt. %, more preferably between 0.001 wt. % to 1 wt. %; most preferably between 0.005 wt. % to 0.5 wt. %.

In another important embodiment, the activator comprises any transition metal-containing compound that can react with a compound that produces free radicals, is associated with a solid. That is, the activators of the present invention are not soluble in the fluid. Activators can be associated with a particle. The particle may be an abrasive, or it may be a carrier for the activator. In some preferred embodiments the activator can be chemically or physically adsorbed on the surface of the abrasive as molecular species, small particles or as a monolayer or a partial layer. In some other embodiments, the abrasive can be a co-formed abrasive in which the activator is homogeneously mixed with another oxide to form solid particles containing an intimate mixture of the activator supported on metal oxide.

Iron associated with an abrasive is particularly useful and is the most preferred activator. Iron associated with silica is the most preferred system. The silica, with its numerous OH groups, can multiply bind with the iron, holding the iron firmly associated with the silica by a number of covalent and/or ionic type bonds. Yet, the plurality of bonds of iron onto the silica, be it absorbed, adsorbed, or coated, allows easy transformation between oxidation states without the iron having a tendency to dis-associate from the silica surface. Surprisingly, iron associated with silica can be used at high pH values, for example from pH 5 to pH 7 and in some cases up to pH 12.

The iron can be associated with the abrasive in the form of a salt, for example a ferric salt, a ferrous salt, in some forms a ferric oxide, and in some forms metallic metal. Generally, metallic metal will be transformed to the ferric or ferrous form in the presence of oxidizers. An additional advantage of iron is that it is environmentally benign and does not pose significant disposal problems.

A system with iron activator, i.e., a slurry having iron coated on solid particles contained within the slurry, shows excellent free radical activity if the amount of activator iron is about 2 to 500 ppm total activator iron, preferably 3 to 100 ppm total activator iron, and for low iron embodiments about 4 to 20 ppm total activator iron. Iron that is not contacting the fluid, including iron for example within a particle matrix where it cannot generate free radicals that can escape the particle structure, is not included in the term activator iron. Iron that cannot activate the formation of free radicals, for example because it is incorporated within a matrix where changes between oxidation states is discouraged, is not included in activator iron. Finally, iron that is chelated or otherwise not available for reaction with the compound that produces free radicals is not included as activator iron. An exemplary slurry has about 10 ppm to about 300 ppm total activator iron, most of it absorbed, adsorbed, or coated onto the abrasive.

The particles comprising the activator compound may be used in CMP slurry in a concentration range of 0.01 wt. % to 2 wt. %, or preferably between 0.05 wt. % to 1 wt. %, or most preferably between 0.07 wt. % and 0.5 wt. %.

The activator may be a non-metal-containing compound. Iodine is a useful with for example hydrogen peroxide to form free radicals. The iodine may be present in an amount sufficient to create the desired free radical activity. In some embodiments, the iodine may be present in an amount ranging from about 1 ppm to about 5000 ppm, preferably between about 10 ppm and about 1000 ppm. Non-metallic activators are often synergistically combined with metal-containing activators

Activator may also be a light-activated activators such as titanium oxides (and light used as an activator). The photoactivated materials of U.S. Pat. No. 6,362,104, the disclosure of which is incorporated by reference, can be used in this capacity.

### Water-Miscible Organic Solvent (Optional)

The polishing compositions of the present invention optionally include one or more water-miscible organic solvents. Examples of water-miscible organic solvents that can be used are ethylene glycol, propylene glycol, 1,4-butanediol, tripropylene glycol methyl ether, propylene glycol propyl ether, diethylene gycol n-butyl ether (e.g. commercially available under the trade designation Dowanol DB), hexyloxypropylamine, poly(oxyethylene)diamine, dimethylsulfoxide, tetrahydrofurfuryl alcohol, glycerol, alcohols, sulfoxides, or mixtures thereof. Preferred solvents are alcohols, diols, or mixtures thereof. Most preferred solvents are diols such as, for example, propylene glycol.

It is believed that, for most applications, the amount of water-miscible organic solvent, if present, will comprise from about 5 to 75% by weight of the composition. Preferably, the solvent comprises from 5 to about 50% by weight and, most preferably, from about 5% to about 30% by weight of the composition.

In some embodiments the compositions of this invention will be free of or substantially free of any or all of the above-listed water-miscible organic solvents or all water-miscible organic solvents added to the composition.

### pH Adjustors

The pH of the composition is desirably on the order of from about pH 1 to about pH 14, and preferably from about pH 1 to about pH 7, and more preferably from about pH 2 to about pH 5.

An acidic or basic pH adjusting agent, such as a suitable acid, base, amine, or any combination thereof can be used to adjust the CMP polishing compositions to the optimized pH value.

The pH adjusting agents include acidic pH adjusting agents, but are not limited to, nitric acid, hydrochloric acid, sulfuric acid, phosphoric acid, other inorganic or organic acids, mixtures thereof, and other chemical reagents that can be used to adjust pH towards the more acidic direction.

The pH adjusting agents also include the basic pH adjusting agents, such as sodium hydride, potassium hydroxide, ammonium hydroxide, tetraalkyl ammonium hydroxide, organic quaternary ammonium hydroxide compounds, organic amines, and other chemical reagents that can be used to adjust pH towards the more alkaline direction.

Preferably, a pH adjusting agent used in the composition does not contain metal ions, such that undesirable metal components are not introduced into the composition.

The amount of pH adjusting agent in a slurry ranges from about 0.0001 wt. % to about 2.0 wt. %.

### Biocide

In certain embodiments, the CMP composition further comprises a biocide. The use of biocide in the enclosed CMP polishing compositions reduces or eliminates bacteria and other microorganisms, especially when the pH values of the CMP polishing compositions is close or around neutral pH conditions.

The biocide biological or growth inhibitor is selected from the group consisting of, tetramethylammonium chloride, tetraethylammonium chloride, tetrapropylammonium chloride, alkylbenzyldimethylammonium chloride, and alkylbenzyldimethylammonium hydroxide, wherein the alkyl chain ranges from 1 to about 20 carbon atoms, sodium chlorite, sodium hypochlorite, and combinations thereof.

The biocide ranges from about 0.0001 weight % to about 0.03 weight %.

### Promoters

As stated above, although metals having multiple oxidation states that are dissolved in the fluid contacting the substrate can act as oxidizers, the most preferred embodiments of this invention have substantially no metals having multiple oxidation states.

In some embodiments, compounds of Al, Ag, Ce, Co, Cr, Cu, Fe, Mo, Mn, Nb, Nd, Ni, Os, Pd, Pt, Rh, Ru, Sc, Sm, Ta, Ti, V, or W in minor amounts dissolved in the solution are useful. These are believed to facilitate the action of the oxidizers, as discussed in U.S. Pat. No. 5,958,288, the disclosure of which is incorporated herein by reference. Metal ions in solution are believed to act as oxidizers with a degree of affinity to the substrate, particularly to metal substrates. If they are able to be oxidized by other oxidizers in the fluid, there will be some synergistic action between the two. In most cases the promoters are believed not to facilitate the action of the free radicals, however. Compounds that form promoters on exposure to a catalyst or substrate, such as those compounds described in U.S. Pat. No. 5,863,838, the disclosure of which is incorporated by reference, are also useful.

In some embodiments of the present invention, the fluid composition contacting the substrate has a small amount of metal ion oxidizers, herein called promoters. Soluble compounds or salts of copper, aluminum, cerium, and iron are used as oxidizers or promoters in CMP solutions. If used, a preferred metal-containing oxidizer promoter is soluble cerium salts or aluminum salts.

The amount of promotor in a slurry ranges from about 0.0001 wt. % to about 1.0 wt. %; preferably 0.0005 wt. % to 0.5 wt. %, more preferably between 0.0025 wt % to 0.1 wt %.

### Chelators

If no-(dissolved)-metal-containing embodiments are desired, the fluid may have chelators. Chelators can essentially trap and isolate metals having multiple oxidation states that are present in dissolved form in the fluid. If dissolved metals are in chelated form, this essentially isolates them from the substrate, which impairs their efficiency as a promoter but prevents metal ion contamination. This can extend the potlife of a slurry of oxidizer, however, and at low concentrations the chelators will not effectively impair the efficiency of the free radicals.

Therefore, only small amounts of chelator should be used. Chelators generally contain organic acid moieties, which can act as free radical quenchers. This could adversely affect the system performance.

In most embodiments of the present invention, the chelator includes, but is not limited to organic carboxylic acids, organic sulfonic acids, and organic phosphoric acids.

Generally, less than 3%, preferably less than 1%, for example less than 0.5% by weight of chelators are preferred.

### Stabilizers

The composition may also include one or more of various optional additives. Suitable optional additives include stabilization agents. These optional additives are generally employed to facilitate or promote stabilization of the composition against settling, flocculation (including precipitation, aggregation or agglomeration of particles, and the like), and decomposition. Stabilizers can be used to extend the pot-life of the oxidizing agent(s), including compounds that produce free radicals, by isolating the activator material, by quenching free radicals, or by otherwise stabilizing the compounds that form free radicals.

Some materials are useful to stabilize hydrogen peroxide. One exception to the metal contamination is the presence of selected stabilizing metals such as tin. In some embodiments of this invention, tin can be present in small quantities, typically less than about 25 ppm, for example between about 3 and about 20 ppm. Similarly, zinc is often used as a stabilizer. In some embodiments of this invention, zinc can be present in small quantities, typically less than about 20 ppm, for example between about 1 and about 20 ppm. In another preferred embodiment the fluid composition contacting the substrate has less than 500 ppm, for example less than 100 ppm, of dissolved metals, except for tin and zinc, having multiple oxidation states. In the most preferred commercial embodiments of this invention, the fluid composition contacting the substrate has less than 9 ppm of dissolved metals having multiple oxidation states, for example less than 2 ppm of dissolved metals having multiple oxidation states, except for tin and zinc. In some preferred embodiments of this invention, the fluid composition contacting the substrate has less than 50 ppm, preferably less than 20 ppm, and more preferably less than 10 ppm of dissolved total metals, except for tin and zinc.

As metals in solution are generally discouraged, it is preferred that those non-metal-containing oxidizers that are typically present in salt forms, for example persulfates, are in the acid form and/or in the ammonium salt form, such as ammonium persulfate.

Other stabilizers include free radical quenchers. As discussed, these will impair the utility of the free radicals produced. Therefore, it is preferred that if present they are present in small quantities. Most antioxidants, i.e., vitamin B, vitamin C, citric acid, and the like, are free radical quenchers. Most organic acids are free radical quenchers, but three that are effective and have other beneficial stabilizing properties are phosphonic acid, the binding agent oxalic acid, and the non-radical-scavenging sequestering agent gallic acid.

In addition, it is believed that carbonate and phosphate will bind onto the activator and hinder access of the fluid. Carbonate is particularly useful as it can be used to stabilize a slurry, but a small amount of acid can quickly remove the stabilizing ions. Stabilization agents useful for absorbed activator can be film forming agents forming films on the silica particle.

Suitable stabilizing agents include organic acids, such as adipic acid, phthalic acid, citric acid, malonic acid, orthophthalic acid; and, phosphoric acid; substituted or unsubstituted phosphonic acids, i.e., phosphonate compounds; nitriles; and other ligands, such as those that bind the activator material and thus reduce reactions that degrade the oxidizing agent, and any combination of the foregoing agents. As used herein, an acid stabilizing agent refers to both the acid stabilizer and its conjugate base.

That is, the various acid stabilizing agents may also be used in their conjugate form. By way of example, herein, an adipic acid stabilizing agent encompasses adipic acid and/or its conjugate base, a carboxylic acid stabilizing agent encompasses carboxylic acid and/or its conjugate base, carboxylate, and so on for the above mentioned acid stabilizing agents. A suitable stabilizer, used alone or in combination with one or more other stabilizers, decreases the rate at which an oxidizing agent such as hydrogen peroxide decomposes when admixed into the CMP slurry.

On the other hand, the presence of a stabilization agent in the composition may compromise the efficacy of the activator. The amount should be adjusted to match the required stability with the lowest adverse effect on the effectiveness of the CMP system. In general, any of these optional additives should be present in an amount sufficient to substantially stabilize the composition. The necessary amount varies depending on the particular additive selected and the particular make up of the CMP composition, such as the nature of the surface of the abrasive component. If too little of the additive is used, the additive will have little or no effect on the stability of the composition. On the other hand, if too much of the additive is used, the additive may contribute to the formation of undesirable foam and/or flocculant in the composition.

Generally, suitable amounts of these optional additives range from about 0.0001 wt. % to about 2.0 wt. % relative to the composition, preferably from about 0.0005 to 1.0%, or more preferably 0.001 to 0.5 wt. %. These optional additives may be added directly to the composition or applied to the surface of the abrasive component of the composition.

In the certain embodiments comprising activator compounds attached to solid surface, stabilizer compound may not be required to prevent degradation of the oxidizer once it is added to the slurry.

Preferred stabilizer is malonic acid.

### Surfactants

If a surfactant is added to the CMP slurry, then it may be an anionic, cationic, nonionic, zwitterionic surfactant or amphoteric surfactant or a combination of two or more surfactants can be employed.

Various anionic and cationic surfactants having molecular weight in the range from less than 1000 to greater than 30,000 are contemplated as dispersants. Included are lauryl sulfate, alkyl polyphosphate, dodecyl benzene sulfonate, disopropylnaphthalene sulfonate, dioctylsulfosuccinate, ethoxylated and sulfated lauryl alcohol, and ethoxylated and sulfated alkyl phenol.

Various cationic surfactants include polyethyleneimine, ethoxylated fatty amine and stearylbenzyldimethylammonium chloride or nitrate. Alternate dispersants contemplated in the present invention include: polyethylene glycols, lecithin, polyvinyl pyrrolidone, polyoxyethylene, isoctylphenyl ether, polyoxyethylene nonylphenyl ether, amine salts of alkylaryl sulfonates, polyacrylate and related salts, polymethacrylate.

In general, a surfactant that may be used in the CMP slurry should be sufficient to achieve effective stabilization of the slurry and will typically vary depending on the particular surfactant selected and the nature of the surface of the metal oxide abrasive. For example, if not enough of a selected surfactant is used, it will have little or no effect on CMP slurry stabilization. On the other hand, too much surfactant in the CMP slurry may result in undesirable foaming and/or flocculation in the slurry.

It also has been found that the addition of a surfactant may be useful to reduce the within-wafer-non-uniformity (WIWNU) of the wafers, thereby improving the surface of the wafer and reducing wafer defects.

While there are many suitable surfactant additives for the composition, preferred surfactant additives include dodecyl sulfate sodium salt, sodium lauryl sulfate, dodecyl sulfate ammonium salt, and any combination thereof. Suitable commercially available surfactants include TRITON DF 16™ manufactured by Union Carbide and SURFYNOL™ manufactured by Air Products and Chemicals.

The surfactant generally is present in the slurry of this invention in an amount ranging from about 0.001% to about 0.2% by weight, and preferably from about 0.001 to about 0.1 weight percent.

Furthermore, the additive may be added directly to the slurry or treated onto the surface of the metal oxide abrasive utilizing known techniques. In either case, the amount of additive is adjusted to achieve the desired concentration in the polishing slurry.

Components of the CMP slurry of invention may be mixed together as a single component slurry or may be provided in two more components to be mixed at point of use. It may be preferable to add an oxidizer at the point of use. In certain preferred embodiments, the slurry may be provided in a concentrated form so that it can be diluted with water and oxidizer be added prior to use. The slurry may be concentrated so that water that can be added at the point of use is preferably 2 times the volume of the slurry or more preferably more than 3 times the volume of the slurry or most preferably more than 5 times the volume of the slurry.

### Working Examples

### General Experimental Procedure

### PARAMETERS:

Å: angstrom(s)—a unit of length
BP: back pressure, in psi units
CMP: chemical mechanical planarization=chemical mechanical polishing
DF: Down force: pressure applied during CMP, units psi
min: minute(s)
ml: milliliter(s)
mV: millivolt(s)
psi: pounds per square inch
PS: platen rotational speed of polishing tool, in rpm (revolution(s) per minute)
SF: polishing composition flow, ml/min
TEOS silicon oxide films by Chemical Vapor Deposition (CVD) using tetraethylk rthosilicate as the precursor
Removal Rate(RR)=(film thickness before polishing—film thickness after polishing)/polish time.

All concentrations of components are wt. % unless otherwise indicated.

In the examples presented below, CMP experiments were run using the procedures and experimental conditions given below.

The CMP tool that was used in the examples is a Mirra, manufactured by Applied Materials, USA. IC1010 polishing pad, supplied by Dow Chemicals was used for CMP process.

200 mm diameter silicon wafers coated with tungsten films TEOS films or tungsten containing SKW patterned structures (Obtained from SKW Associates, Inc. 2920 Scott Blvd. Santa Clara, CA 95054 were used. Polish time for blanket films was one minute. Tungsten removal rates were measured using sheet resistance measurement techniques. TEOS removal was measured using optical techniques. Patterned wafers were polished for time based on eddy current technique on the Ebarapolisher. Polishing time for patterned wafer was 15 seconds past the end point identified by the eddy current end point technique. Patterned wafers were analyzed with a KLA Tencor P15 Profiler (large feature sizes) or an AFM tool (small feature sizes).

The polishing was performed using at 3 psi downforce, 80 RPM table speed, 81 RPM carrier speed 81 RPM and 100 ml/min slurry flow rate.

### Example 1

Base formulation 1 comprised 0.01 wt % ferric nitrate, 0.08 wt. % malonic acid (stabilizer), 2.5 wt. % hydrogen peroxide, 0.1 glycine, 0.0005 wt. % cetyltrimethylammonium hydroxide in water with pH adjusted to 2.3.

Different abrasive particles were added to the base formulations to make the polishing slurries. All the particles used in this study were obtained from Fuso Chemical Co, Ltd. (2-5, Nihonbashi-Honcho 2-chome, Chuo-ku, Tokyo 103-00, Japan).

Fuso PL-3 is a cocoon shaped silica particle with particle size of approximately 70 nm. Fuso PL-3C is a cocoon shaped silica particle surface modified with aminopropyl trialkoxysilane compound, with particle size of approximately 70 nm. Fuso PL-3L is a spherical silica particle with particle size of approximately 70 nm.

TABLE 1

| | | W RR | TEOS RR | W:TEOS RR |
|---|---|---|---|---|
| Formulation | Abrasive | (Å/min) | (Å/min) | selectivity |
| 1 | 1.5 wt % Fuso PL-3L | 1917 | 576 | 3 |
| 2 | 1.5 wt % Fuso PL-3 | 5747 | 508 | 11 |
| 3 | 1.5 wt % Fuso PL-3C | 5788 | 131 | 44 |
| 4 | 1.0 wt % Fuso PL-3C | 5932 | 90 | 66 |
| 5 | 0.5 wt % Fuso PL-3C | 6073 | 79 | 77 |
| 6 | 0.1 wt % Fuso PL-3C | 4518 | 49 | 92 |
| 7 | 0.1 wt % Fuso PL-3C | 3489 | 30 | 116 |
| | with 1.0 wt % H₂O₂ | | | |

Formulation 7 had same amount of chemicals as formulation 6, except it had 1.0 wt. % hydrogen peroxide.

Table 1 and FIG. 1 summarized tungsten and TEOS removal rates for slurries formulated using different particles.

Data in Table 1 has shown that by using alkoxy silane amine modified abrasive particles the removal rate of tungsten was increased accompanied by the decreased removal rate of TEOS resulting in a greatly increased removal selectivity of tungsten vs TEOS blanket from 3 or 11 to more than 44.

The polish rates of tungsten blanket films at 3.0 psi downforce and 80 RPM table speed was shown to be greater than 2500 Å/min., greater than 3000 Å/min., greater than 4000 Å/min., or even greater than 4500 Å/min.

### Example 2

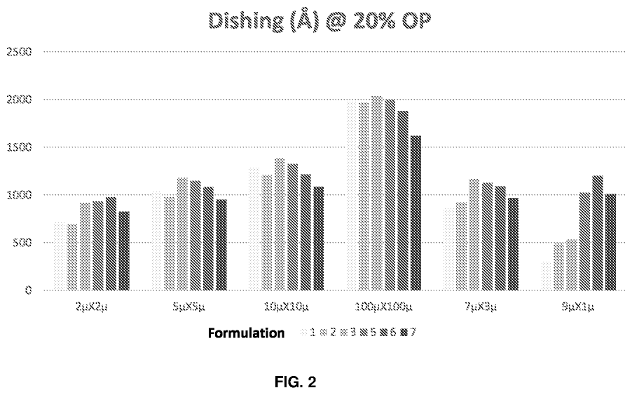

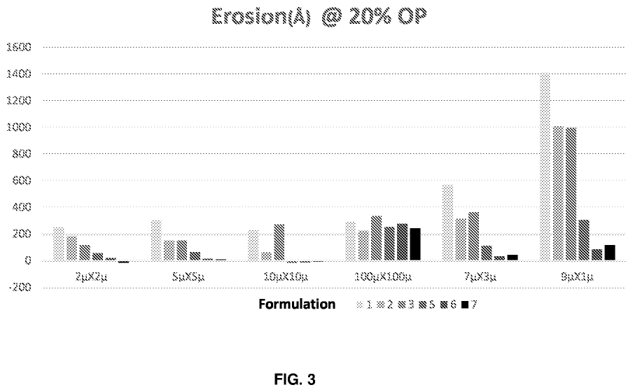

Dishing and erosion data for different patterned structures having different line features (2 μmX2 μm. 5μmX5 μm, 10μmX10 μm, 100μmX100 μm, 7μmX3 μm, 9μmX1 μm) at 20% overpolish for these formulations were summarized in Table 2 and FIG. 2; and Table 3 and FIG. 3 respectively.

TABLE 2
Dishing (Å)

| Formu- | | | | | | |
|---|---|---|---|---|---|---|
| lation | 2μ × 2μ | 5μ × 5μ | 10μ × 10μ | 100μ × 100μ | 7μ × 3μ | 9μ × 1μ |
| 1 | 713 | 1036 | 1283 | 1986 | 857 | 302 |
| 2 | 694 | 979 | 1211 | 1973 | 929 | 492 |
| 3 | 922 | 1183 | 1388 | 2043 | 1174 | 535 |
| 5 | 934 | 1152 | 1328 | 2004 | 1130 | 1027 |
| 6 | 981 | 1088 | 1220 | 1884 | 1095 | 1203 |
| 7 | 830 | 955 | 1091 | 1625 | 974 | 1014 |

TABLE 3
Erosion (Å)

| Formu- | | | | | | |
|---|---|---|---|---|---|---|
| lation | 2μ × 2μ | 5μ × 5μ | 10μ × 10μ | 100μ × 100μ | 7μ × 3μ | 9μ × 1μ |
| 1 | 254 | 307 | 228 | 295 | 573 | 1412 |
| 2 | 182 | 153 | 64 | 226 | 314 | 1007 |
| 3 | 118 | 151 | 274 | 337 | 365 | 997 |
| 5 | 58 | 65 | −14 | 254 | 113 | 306 |
| 6 | 22 | 15 | −12 | 279 | 33 | 86 |
| 7 | −14 | 11 | −8 | 244 | 45 | 117 |

Data in dishing and erosion as shown in Table 2 and 3 has shown that by using alkoxy silane amine modified abrasive particles, the removal selectivity of tungsten vs TEOS blanket has increased without affecting the dishing and erosion of array structures.

Dishing and erosion of some array structures were improved.

The erosion of 9×1 micron array (9 micron wide tungsten line width separated by 1 micron wide dielectric line) measured on a patterned wafer was less than 1000 Å, less than 500 Å, or even less than 300 Å when the wafer was polished for 15 seconds additional time after the pattern wafer polish end point detected by using is suitable method such as eddy current measurement or optical end point detection.

### Example 3

The following formulations were made for comparison:

| Formulation | 8 | 9 | 10 | 11 | 12 |
|---|---|---|---|---|---|
| Glycine (wt. %) | 0.1000 | 0.1000 | 0.1000 | 0.1000 | 0.1000 |
| Adjust pH to 2.3 with Nitric Acid | | | | | |
| polyacrylamide MW (10,000) (wt. %) | 0.002 | | | | |
| Chitosan (10-50 KDa)(wt. %) | 0.003 | 0.003 | 0.0015 | 0.0015 | 0.0015 |
| Jeffamine T-403 (wt. %) | | 0.002 | 0.002 | 0.002 | 0.002 |
| Iron(III) nitrate nonahydrate(wt. %) | 0.01 | 0.01 | 0.01 | 0.01 | 0.01 |
| Fuso PL-2C(wt. %) | 0.050 | 0.050 | 0.050 | 0.075 | 0.100 |
| Malonic acid(wt. %) | 0.08 | 0.08 | 0.08 | 0.08 | 0.08 |
| H₂O₂(wt. %) | 2.00 | 2.00 | 2.00 | 2.00 | 2.00 |

The ingredients were mixed into DI water and stirred. The table represents point of use formulations.

### Example 4: Effect of Chitosan on Erosion

The following table summarizes the formulations evaluated for the effect of erosion inhibition of chitosan on a TEOS dielectric:

| | |
|---|---|
| Glycine(wt. %) | 0.1000 |
| Adjust pH to 2.3 with Nitric Acid | |
| polyacrylamide MW (10,000) (wt. %) | 0.002 |
| Chitosan (10-50 KDa)(wt. %) | varied |
| Iron(III) nitrate nonahydrate(wt. %) | 0.01 |
| Fuso PL-2C(wt. %) | 0.050 |
| Malonic acid(wt. %) | 0.08 |
| H2O2(wt. %) | 2.00 |

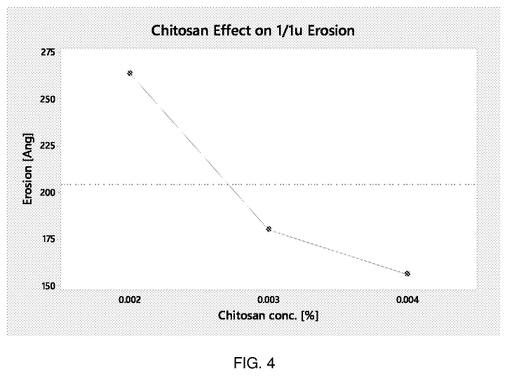

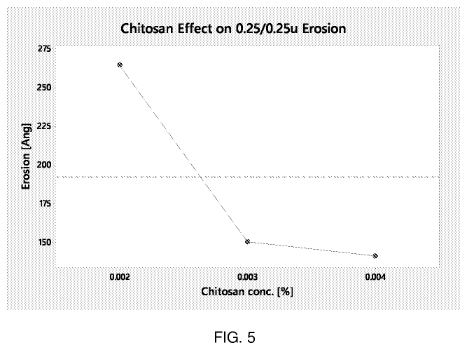

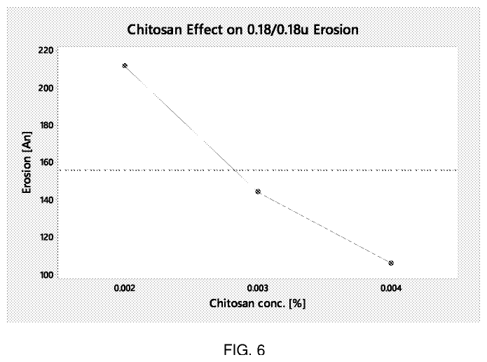

FIGS. 4 to 6 illustrate the erosion inhibiting results of varying the amount of chitosan on features of different sizes in a TEOS dielectric layer.

### Example 5

Formulations 8 and 9 above were tested relative to each other for their effect on tungsten dishing and dielectric erosion.

The following tables show that chitosan and polyacrylamide when used together show and improvement in dishing and erosion relative to a similar formulation wherein the polyacrylamide is replaced with Jeffamine® T-403.

| | Formulation 8 | Formulation 9 |
|---|---|---|
| Dishing Feature [μ] | | |
| 0.18/0.18 | 66 | 85 |
| 0.25/0.25 | 57 | 94 |
| ′0.5/0.5 | 60 | 77 |
| 1/1 | 70 | 90 |
| 10/10 | 270 | 302 |
| 50/50 | 582 | 643 |
| Erosion feature (μm) | | |
| 0.18/0.18 | 119 | 67 |
| 0.25/0.25 | 147 | 189 |
| 0.5/0.5 | 177 | 130 |
| 1/1 | 156 | 97 |

### Example 6: Effect on Tungsten Dishing

The following formulations were prepared for evaluation of tungsten dishing:

| | | | | | No Topo |
|---|---|---|---|---|---|
| Formulations | DBU | Dual | Polyacrylam. | Chitosan | add |
| Glycine(wt. %) | 0.1000 | 0.1000 | 0.1000 | 0.1000 | 0.1000 |
| DBU(wt. %) | 0.02 | | | | |
| polyacrylamide MW | | 0.001 | 0.001 | | |
| (10,000) (wt. %) | | | | | |
| Chitosan(10-50 | | 0.001 | | 0.001 | |
| KDa)(wt. %) | | | | | |
| Iron(III) nitrate | 0.01 | 0.01 | 0.01 | 0.01 | 0.01 |
| nonahydrate(wt. %) | | | | | |
| Fuso PL-3C(wt. %) | 0.100 | 0.100 | 0.100 | 0.100 | 0.100 |
| Malonic acid(wt. %) | 0.08 | 0.08 | 0.08 | 0.08 | 0.08 |
| Final pH (Nitric Acid) | 2.30 | 2.30 | 2.30 | 2.30 | 2.30 |
| H₂O₂(wt. %) | 2.00 | 2.00 | 2.00 | 2.00 | 2.00 |

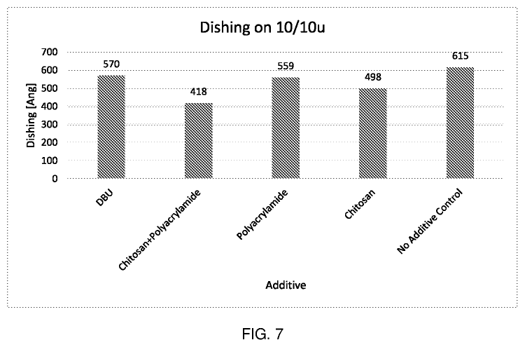

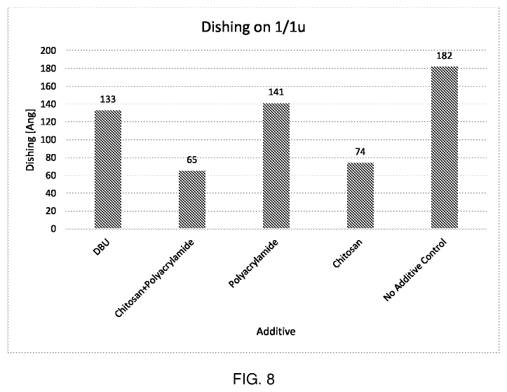

The results are illustrated in FIG. 7 and FIG. 8 where it is shown that a synergy in minimizing tungsten dishing is observed between chitosan and polyacrylamide and different feature sizes.

### Example 7

Base formulation as reference for Example 7 comprised 0.02 wt. % ferric nitrate, 0.08 wt. % malonic acid (as stabilizer), 3.0 wt. % hydrogen peroxide, 0.1 wt. % glycine, 0.3 wt. % Fuso PL-2C high purity colloidal silica particles as abrasives, and 0.00056 wt. % Neolone M-10 as biocide in water with pH adjusted to 2.3.

Working formulations in Example 7 were the base formulation plus added chitosan with molecular weight 10-50 KDa or with molecular weight 80-200KDa as additives at 30 ppm or 60 ppm concentrations respectively. pH adjusted to 2.3 for all testing formulations.

The effects of chitosan molecular weights and concentrations on the W and TEOS film removal rates are listed in Table 4.

TABLE 4
Effects of Chitosan MW and Concentrations on W and TEOS RR

| Formulation | W RR | TEOS RR |
|---|---|---|
| Ref. w/o Chitosan | 4570 | 20 |
| 10-50 kDa Chitosan 30 ppm | 4993 | 21 |
| 10-50 kDa Chitosan 60 ppm | 4616 | 18 |
| 80-200 kDa Chitosan 30 ppm | 4979 | 23 |
| 80-200 kDa Chitosan 60 ppm | 4289 | 40 |

As the results shown in Table 4, when the two different molecular weights of chitosan used as additives at 30 ppm concentrations, the W film removal rates were increased by about 9%, and TEOS film removal rates were minimally changed.

### Example 8

Same formulation as listed in Example 7 were used in Example 8. The effects of chitosan molecular weights and concentrations on the W line dishing were summarized in Table 5.

TABLE 5
Effects of Chitosan MW and Concentrations on W Line Dishing

| | Samples | | | | |
|---|---|---|---|---|---|
| | | 10-50 KDa | 10-50 KDa | 80-200 KDa | 80-200 KDa |
| | Ref. | Chitosan | Chitosan | Chitosan | Chitosan |
| | W Line (μm)/Dishing | | | | |
| | No Chitosan | 30 ppm | 60 ppm | 30 ppm | 60 ppm |
| 0.18 × 0.18 | 213 | 188 | 113 | 193 | 104 |
| 1 × 1 | 510 | 510 | 451 | 605 | 403 |
| 7 × 3 | 208 | 295 | 254 | 301 | 213 |
| 50 × 50 | 1337 | 1361 | 872 | 1444 | 765 |

As the results shown in Table 5, W line dishing was improved using suitable molecular weight and concentration of chitosan.

### Example 9

Base formulation as reference for Example 9 is the same formulation as listed in Example 7.

The effects of chitosan molecular weights and concentrations on erosion are listed in Table 6.

TABLE 6
Effects of Chitosan MW and Concentrations on Erosion

| | Samples | | | | |
|---|---|---|---|---|---|
| | | 10-50 KDa | 10-50 KDa | 80-200 KDa | 80-200 KDa |
| | Ref. | Chitosan | Chitosan | Chitosan | Chitosan |
| | Erosion(μm) | | | | |
| | No | | | | |
| | Chitosan | 30 ppm | 60 ppm | 30 ppm | 60 ppm |
| 0.18 × 0.18 | 410 | 314 | 92 | 412 | 285 |
| 1 × 1 | 382 | 261 | 120 | 295 | 166 |
| 7 × 3 | 457 | 454 | 339 | 397 | 197 |
| 50 × 50 | 16 | 4 | 77 | 10 | 67 |

As the results shown in Table 6, erosion was improved for all the formulations except for higher concentration of chitosan for 50×50 μm.

The foregoing examples and description of the embodiments should be taken as illustrating, rather than as limiting the present invention as defined by the claims. As will be readily appreciated, numerous variations and combinations of the features set forth above can be utilized without departing from the present invention as set forth in the claims. Such variations are intended to be included within the scope of the following claims.

1. A polishing composition comprising:
water;
from 0.05 wt. % to 10.0 wt. %; or 0.01 wt. % to 2.0 wt. % of abrasive particles comprising silica;
from 0.0005 wt. % to 2 wt. %, or 0.001 wt. % to 1 wt. % of a soluble activator compound;
from 0.5 wt. % to about 10.0 wt. %; or 0.5 wt. % to 5.0 wt. % of an oxidizer;
at least one nitrogen-containing polymeric additive selected from the group consisting of chitosan, a polyacrylamide, a polyamine, a polyethylenimine, poly(N-vinyl-N-methyl amine), polyaminostyrene, a polyvinylamine, a polyvinyl amine; and
optionally,
a corrosion inhibitor;
a stabilizer;
a pH-adjusting agent;
a water-miscible organic solvent;
a surfactant; and
a biocide or biological growth inhibitor,
wherein the polishing composition has a pH between 2 and 14 or and 7.

2. The polishing composition of claim 1 wherein the silica particles are surface treated with an alkoxy silane amine and have a zeta potential ≥15 mV ≥25 mV.

3. The polishing composition of claim 1, wherein the abrasive particles have a particle size of from 20 to 200 nm.

4. The polishing composition of claim 1, wherein the at least one nitrogen-containing polymeric additive comprises chitosan, wherein the chitosan is represented by the structure 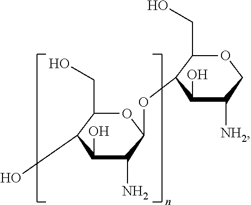
wherein n is a number from 20 to 2250 or
200 to 1000; chitosan employed is from 70% to 90% or 75% to 85% deacetylated.

5. The polishing composition of claim 1, wherein the at least one nitrogen-containing polymeric additive comprises a chitosan represented by the structure 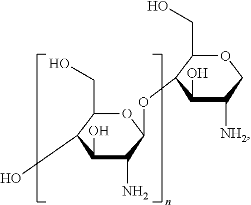
wherein n is a number from 20 to 2250 or 200 to 1000; chitosan employed is from 70% to 90% or 75% to 85% deacetylated a polyacrylamide; and
polyacrylamide or a polyamine.

6. (canceled)

7. The polishing composition of claim 5, wherein the polyamine is a polyether-polyamine having the following structure 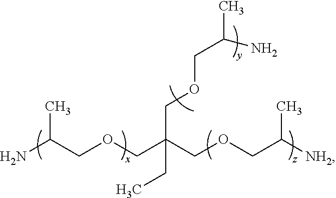
wherein (x+y+z)=5 or 6.

8. The polishing composition of claim 1, wherein the silica particles are surface treated with an alkoxy silane amine and have a zeta potential ≥15 mV, or ≥25 mV; and the alkoxy silane amine is selected from the group consisting of (3-Aminopropyl)trimethoxysilane, 3-aminopropyltriethoxysilane, 4-aminobutyltriethoxysilane, m-aminophenyltrimethoxysilane, p-aminophenyltrimethoxysilane, 3-aminopropyltris(methoxyethoxy ethoxy)silane, 11-aminoundecyltriethoxysilane, 2-(4-pyridylethyl)triethoxysilane, and combinations thereof.

9. The polishing composition of claim 1, wherein the pH is from 2 to 5.

10. The polishing composition of claim 1, wherein the soluble activator compound is selected from the group consisting of ammonium iron (III) oxalate trihydrate, iron(Ill) citrate tribasic monohydrate, iron(Ill) acetylacetonate and ethylenediamine tetraacetic acid, iron (Ill) sodium salt hydrate; and the activator compound coated on solid particles are iron coated on solid particles; and the oxidizer is selected from the group consisting of peroxy compound selected from the group consisting of hydrogen peroxide, urea peroxide, peroxyformic acid, peracetic acid, propaneperoxoic acid, substituted or unsubstituted butaneperoxoic acid, hydroperoxy-acetaldehyde, potassium periodate, ammonium Peroxymonosulfate; and non-per-oxy compound selected from the group consisting of ferric nitrite, KClO₄, KBrO₄, KMnO₄.

11. The polishing composition of claim 1, wherein the soluble activator is selected from the group consisting of ferric nitrate, ferric sulfate, ferric citrate, iron gluconate, and combinations thereof; and the composition has a pH<4.

12. (canceled)

13. The polishing composition of claim 1, wherein the polishing composition further comprises at least one selected from the group consisting of the water-miscible organic solvent being an alcohol;
the corrosion inhibitor selected from the group consisting of glycine, lysine, alanine, proline, serine, arginine and combinations thereof;
the stabilizer selected from the group consisting of an organic acid and its conjugated base selected from the group consisting of adipic acid, phthalic acid, citric acid, malonic acid, orthophthalic acid; phosphoric acid; substituted or unsubstituted phosphonic acids, nitriles; and combinations thereof;
the pH-adjusting agent selected from the group consisting of (a) nitric acid, sulfuric acid, tartaric acid, succinic acid, citric acid, malic acid, malonic acid, various fatty acids, various Polycarboxylic acids and combinations thereof to lower pH of the polishing composition; and (b) potassium hydroxide, sodium hydroxide, ammonia, tetraethylammonium hydroxide, ethylenediamine, piperazine, polyethyleneimine, modified polyethyleneimine, and combinations thereof to raise pH of the polishing composition; and
the surfactant selected from the group consisting of (a) non-ionic surface wetting agents; (b) anionic surface wetting agents; (c) cationic surface wetting agents; (d) ampholytic surface wetting agents; and combinations thereof; and the amount of surfactant ranges from about 0.0001 wt. % to about 1.0 wt. %, and Preferably from about 0.010 wt. % to about 0.1 wt. %.

14. (canceled)

15. (canceled)

16. (canceled)

17. (canceled)

18. A polishing composition comprising:
water;
from 0.05 wt. % to 10.0 wt. %; 0.01 wt. % to 2.0 wt. %; or 0.01 wt. % to 0.5 wt. % of abrasive particles comprising silica;
from 0.0005 wt. % to 2 wt. %, 0.001 wt. % to 1 wt. %; or 0.005 wt. % to 0.5 wt. % of a soluble activator compound;
from 0.5 wt. % to about 10.0 wt. %; 0.5 wt. % to 5.0 wt. %; or 1.0 wt. % to 3.0 wt. % of an oxidizer;
at least one water-soluble cationic polysaccharide represented by the general formula: 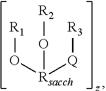
wherein R_{sacch} is the residue of a polysaccharide repeat unit derived from the polysaccharide starting material;
Q is selected from the group consisting of 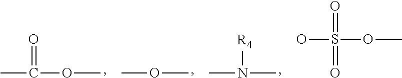
wherein R₄ is selected from the group consisting of 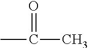
and a mixture of 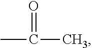
and hydrogen;
Z is from 50 to about 20,000; and
each of R1, R2, and R3 is independently represented by the substituent structural formula: 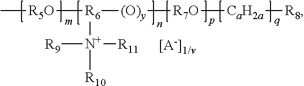
wherein
A is an anion;
a is an integer of from 1 to about 3;
m is an integer of from 0 to about 6;
n is an integer of from 0 to about 3, provided that the level of cationic substitution, CS, defined by the average moles of quaternary nitrogen atoms per mole polysaccharide repeat unit is greater than 0;
p is an integer of from 0 to about 6;
q is 0 or 1;
each R₅ and R₇ is individually ethylene, a propylene or a hydroxypropylene;
R₆ is a di- or trivalent, branched or straight chain, saturated or unsaturated hydrocarbon having from 2 to about 4 carbon atoms, provided there are at least 2 carbon atoms between the nitrogen atom and any oxygen atom;
R₈ is hydrogen, hydroxyl, Rₕ, carboxyl or alkali metal or amine carboxylate, provided that when q is 0 then R₈ is hydrogen or Rₕ;
each R₉, R₁₀ and R₁₁ is individually Rh, alkyl, aryl, aralkyl, alkaryl, cycloalkyl, alkoxyaryl or alkoxyalkyl, having at least two carbon atoms separating the oxygen atom in the alkoxyaryl or alkoxyalkyl group from the nitrogen atom;
Rₕ is a hydrophobic group containing an alkyl group having at least 8 carbon atoms;
v is equal to the valence of A; and
y is 0 or 1;
wherein the polishing composition has a pH between 2 and 14 or 1 and 7.

19. The polishing composition of claim 18 further comprising a polyether-polyamine or a polyacrylamide; wherein the polyether-polyamine has following structure 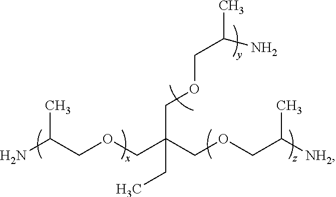
wherein (x+y+z)=5 or 6.

20. (canceled)

21. A polishing method for chemical mechanical planarization of a semiconductor device comprising at least one surface containing tungsten, the method comprising the steps of:
a) contacting the at least one surface containing tungsten with a polishing pad;
b) delivering the polishing composition of claim 1 or claim 18 to the at least one surface containing tungsten; and
c) polishing the at least one surface containing tungsten with the polishing composition;
wherein polishing rate for tungsten at 3 psi down-force is >1000 Å/min.

22. The polishing method of claim 21, wherein the semiconductor device further contains a dielectric layer selected from the group consisting of TEOS; a porous or a non-porous low-K film comprising of silicon, carbon, oxygen and hydrogen; a porous low K material with a capping layer of a non-porous material; and the removal rate selectivity between tungsten and the dielectric layer is >1.

23. The polishing method of claim 22, wherein the dielectric layer is TEOS;
polishing rate for TEOS at 3 psi down-force is <150 Å/min., preferably 80 Å/min., or
more preferably <50 Å/min.; and the removal rate selectivity between tungsten and TEOS is >25, preferably >40, or more preferably >90.

24. A polishing system for chemical mechanical planarization of a semiconductor device comprising at least one surface containing tungsten; comprising
a) the at least one surface containing tungsten;
b) a polishing pad; and
c) the polishing composition of claim 1 or claim 18,
wherein the at least one surface containing tungsten is in contact with the polishing pad and the polishing composition.

25. The polishing system of claim 24, wherein the semiconductor device further contains a dielectric layer selected from the group consisting of TEOS; a porous or a non-porous low-K film comprising of silicon, carbon, oxygen and hydrogen; a porous low K material with a capping layer of a non-porous material; and the removal rate selectivity between tungsten and the dielectric layer is >1.

26. The polishing system of claim 25, wherein the dielectric layer is TEOS; polishing rate for TEOS at 3 psi down-force is <150 Å/min., preferably 80 Å/min., or more preferably <50 Å/min.; and the removal rate selectivity between tungsten and TEOS is >25, preferably >40, or more preferably >90.

27. The polishing method of claim 21, wherein the polishing composition has a pH from 2 to 5.
